(19) United States
(12) Patent Application Publication
(10) Pub. No.: US 2015/0007875 A1
(43) Pub. Date: Jan. 8, 2015

(54) PIN PHOTOVOLTAIC CELL AND PROCESS OF MANUFACTURE

(71) Applicants: Jose Briceno, Tokyo-to (JP); Koji MATSUMARU, Nagaoka-Shi (JP)

(72) Inventors: Jose Briceno, Tokyo-to (JP); Koji MATSUMARU, Nagaoka-Shi (JP)

(21) Appl. No.: 14/214,942

(22) Filed: Mar. 16, 2014

Related U.S. Application Data
(63) Continuation-in-part of application No. 13/844,686, filed on Mar. 15, 2013.
Application No. 13/844,686 is a continuation-in-part of application No. 13/844,298, filed on Mar. 15, 2013.
Application No. 13/844,298 is a continuation-in-part of application No. 13/844,428, filed on Mar. 15, 2013.
Application No. 13/844,428 is a continuation-in-part of application No. 13/844,521, filed on Mar. 15, 2013.
Application No. 13/844,521 is a continuation-in-part of application No. 13/844,747, filed on Mar. 15, 2013.
(60) Provisional application No. 61/801,145, filed on Mar. 15, 2013.
(60) Provisional application No. 61/800,800, filed on Mar. 15, 2013.
(60) Provisional application No. 61/800,912, filed on Mar. 15, 2013.
(60) Provisional application No. 61/801,019, filed on Mar. 15, 2013.
(60) Provisional application No. 61/801,244, filed on Mar. 15, 2013.
(60) Provisional application No. 61/619,410, filed on Apr. 2, 2012.
(60) Provisional application No. 61/722,693, filed on Nov. 5, 2012.
(60) Provisional application No. 61/655,449, filed on Jun. 4, 2012.
(60) Provisional application No. 61/738,375, filed on Dec. 17, 2012.
(60) Provisional application No. 61/715,283, filed on Oct. 17, 2012.
(60) Provisional application No. 61/715,286, filed on Oct. 18, 2012.
(60) Provisional application No. 61/715,287, filed on Oct. 18, 2012.

(51) Int. Cl. H01L 31/077; H01L 31/18; H01L 31/0224

(52) U.S. Cl. CPC H01L 31/077; H01L 31/022475; H01L 31/022483; H01L 31/022466; H01L 31/1884
USPC 136/256; 136/252; 136/261; 438/98; 438/72

(57) ABSTRACT

A PIN photovoltaic (PIN PV) device is composed of a first electrode layer, a p-type semiconductor layer, an intrinsic semiconductor layer, an n-type semiconductor substrate, and a back surface electrode. Also described is a method for manufacturing a PIN PV device. In a first embodiment, the method includes cleaning an n-type semiconductor substrate; introducing an inert gas under vacuum and a high temperature to form a high resistivity layer on the top surface of the substrate; forming or depositing a p-type semiconductor layer on the high resistivity layer; forming a transparent electrode layer on the p-type semiconductor layer; and forming a metal electrode on the bottom surface of the substrate. In a second embodiment, an SiC or SiO2 isolation layer is formed on the bottom surface of the substrate after initial cleaning of the wafer before the high resistivity layer is formed on the top of the substrate.

### CROSS-REFERENCE TO RELATED APPLICATIONS

This application claims the benefit of U.S. application Ser. No. 13/844,686, filed Mar. 15, 2013 (Attorney Docket No. 44671-047 (P7)); U.S. Provisional Application No. 61/761,342, filed Feb. 6, 2013 (Attorney Docket No. 44671-047 (P7)); U.S. application Ser. No. 13/844,298, filed Mar. 15, 2013 (Attorney Docket No. 44671- 033 (P2)); U.S. Provisional Application No. 61/619,410, filed Apr. 2, 2012 (Attorney Docket No. 44671-033 (P2)); U.S. application Ser. No. 13/844,428, filed Mar. 15, 2013 (Attorney Docket No. 44671-034 (P3)); U.S. Provisional Application No. 61/722,693, filed Nov. 5, 2012 (Attorney Docket No. 44671-034 (P3)); U.S. application Ser. No. 13/844,521, filed Mar. 15, 2013 (Attorney Docket No. 44671-035 (P4)); U.S. Provisional Application No. 61/655,449, filed Jun. 4, 2012 (Attorney Docket No. 44671-035 (P4)); U.S. application Ser. No. 13/844,747, filed Mar. 15, 2013 (Attorney Docket No. 44671-038 (P5)); U.S. Provisional Application No. 61/738,375, filed Dec. 17, 2012 (Attorney Docket No. 44671-038 (P5)); U.S. Provisional Application No. 61/715,283, filed Oct. 17, 2012 (Attorney Docket No. 44671-041 (P12)); U.S. Provisional Application No. 61/715,286, filed Oct. 18, 2012 (Attorney Docket No. 44671-043 (P13)); U.S. Provisional Application No. 61/715,287, filed Oct. 18, 2012 (Attorney Docket No. 44671-044 (P14)); U.S. Provisional Application No. 61/801,019, entitled Manufacturing Equipment for Photovoltaic Devices, filed 15 Mar. 2013 (Attorney Docket No. 44671-050 (P 32)); U.S. Provisional Application No. 61/800,912, entitled Infrared Photovoltaic Device, filed 15 Mar. 2013 (Attorney Docket No. 44671-049 (P 10)); U.S. Provisional Application No. 61/800,800, entitled Hybrid Transparent Electrode Assembly for Photovoltaic Cell Manufacturing, filed 15 Mar. 2013 (Attorney Docket No. 44671-048 (P23)); U.S. Provisional Application No. 61/801,145, entitled PIN Photo-voltaic device and Manufacturing Method, filed 15 Mar. 2013 (Attorney Docket No. 44671-051 (P 17)), and U.S. Provisional Application No. 61/801,244, entitled Infrared Photo-voltaic device and Manufacturing Method, filed 15 Mar. 2013 (Attorney Docket No. 44671-052 (P36)), the entireties of which are incorporated by reference as if fully set forth herein.

This application is related to copending U.S. patent application Ser. No. 13/844,686, filed 15 Mar. 2013 (docket number P7, sub case 003); the entirety of which is incorporated by reference as if fully set forth herein.

### FIELD OF THE INVENTION

The present invention relates to photovoltaic devices, and in particular, a PIN photovoltaic device structure with improved photovoltaic properties and a simplified method of manufacture.

### BACKGROUND OF THE INVENTION

A solar cell (also called a photovoltaic cell) is an electrical device that converts the energy of light directly into electricity by the photovoltaic effect. Prior art solar cell technology typically utilizes crystalline silicon as a main ingredient, and in some other cases, inexpensive poly-crystalline silicon or other compound semiconductors. In addition, other technologies use organic materials for the so-called dye-sensitized solar cells. Prior art crystalline silicon solar cells are often fabricated by forming a high concentration n-type layer on a p-type silicon substrate. This high concentration n-type layer is generally formed by a process of ion implantation, or diffusion, introducing the n-type dopant phosphorous, to form a PN junction, followed by an annealing process. Once the PN junction is so formed, anode and cathode electrodes are formed to complete the photovoltaic cell.

Recently, an intrinsic layer between the P and N layers to create a so-called PIN junction cell has also been added, to increase cell efficiency. However, in the same manner as the PN junction solar cell, the manufacturing process for PIN junction cells is based on impurity doping methods that are expensive and use toxic materials. It is highly desirable to have a manufacturing process for photovoltaic materials that reduces or eliminates toxic additives.

The conventional methods for manufacturing photovoltaic materials also require a multi-step process, or different processes, with each step possibly taking place at a different apparatus and at different times, and requiring its own management and resources. It is highly desirable to have a manufacturing process for photovoltaic materials that reduces the number of necessary processes or steps to reduce costs.

### BRIEF SUMMARY OF THE PREFERRED EMBODIMENTS OF THE INVENTION

Preferred embodiments of the present invention provide a PIN photovoltaic device and a method of manufacturing the device. Embodiments include a method for manufacturing using a heating process to create one or more photovoltaic structures on a bulk semiconductor substrate.

The PIN photovoltaic (PIN PV) device is composed of a first electrode layer, a p-type semiconductor layer, an intrinsic semiconductor layer, an n-type semiconductor substrate, and a back surface electrode.

The method for manufacturing the PIN PV device of the present invention is preferably a toxic material free process, which lowers the overall manufacturing cost. In a first embodiment, the method begins by cleaning an n-type semiconductor substrate; introducing an inert gas under vacuum and a high temperature to form a high resistivity layer on the top surface of the substrate; depositing a p-type semiconductor layer on the high resistivity layer; forming a transparent electrode layer on the p-type semiconductor layer; and forming a metal electrode on the bottom surface of the substrate.

In a second embodiment, the method begins by cleaning an n-type semiconductor substrate; forming an SiC or SiO2 isolation layer on the bottom surface of the substrate; introducing an inert gas under vacuum and a high temperature to form a high resistivity layer on the top surface of the substrate; depositing a p-type semiconductor layer on the high resistivity layer; forming a transparent electrode layer on the p-type semiconductor layer; and forming a metal electrode on the bottom surface of the substrate.

### BRIEF DESCRIPTION OF THE DRAWINGS

Preferred embodiments of the present invention are illustrated by way of example, and not by way of limitation, in the figures of the accompanying drawings and in which like reference numerals refer to similar elements and in which:

FIG. 1 is a cross-sectional view of a PIN PV device during one stage of the manufacturing process after the PV device has been formed according to one embodiment of the present invention.

FIG. 2 is a cross-sectional view of a PIN PV device during one stage of the manufacturing process after the PV device has been formed according to another embodiment of the present invention.

FIG. 3 is a flow diagram illustrating an example of the steps of the process for manufacturing the PV device shown in FIG. 2.

### DETAILED DESCRIPTION OF PREFERRED EMBODIMENTS OF THE INVENTION

In the following description numerous specific details have been set forth to provide a more thorough understanding of embodiments of the present invention. It will be appreciated however, by one skilled in the art, that embodiments of the invention may be practiced without such specific details or with different implementations for such details. Additionally some well-known structures have not been shown in detail to avoid unnecessarily obscuring the present invention.

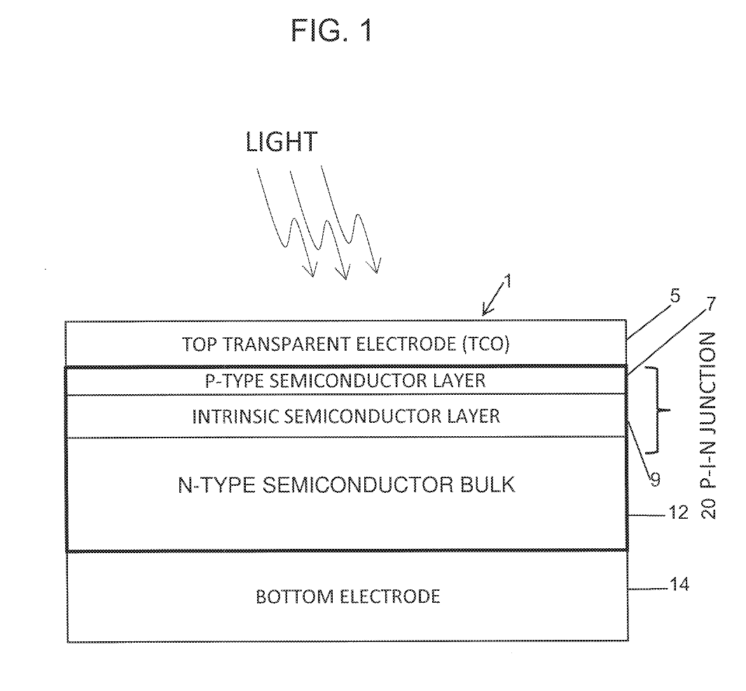

FIG. 1 is a diagrammatic view of a cross-section of a photovoltaic (PV) device 1 during an initial stage of the manufacturing process according to one embodiment of the present invention. Device 1 includes an n-type semiconductor substrate 12 on the top of which an intrinsic, high resistivity semiconductor layer 9 is formed. A p-type semiconductor layer 7 is formed on top of the high resistivity semiconductor layer 9. The intrinsic semiconductor layer 9 has a resistivity that is at least 10 times higher of that of semiconductor substrate 12. An electrode layer 5 is formed on top of p-type semiconductor layer 7. Electrode layer 5 is typically made of a transparent conductive oxide (TCO). Formation of these layers 5, 7, and 9 may be by any means known in the art including impurity diffusion or doping of the semiconductor substrate. Finally, a bottom or back surface electrode is 14 is formed on the bottom surface of substrate 12. Electrode 14 is composed of a single, or multiple metal layer that will have an ohmic contact with the semiconductor substrate. Note that layers 12, 9, and 7 define the P-I-N junction 20 of the device 1.

### BEST MODE FOR CARRYING OUT THE INVENTION

### Example 1

### Top p-type Layer by Doping (diffusion), Implantation

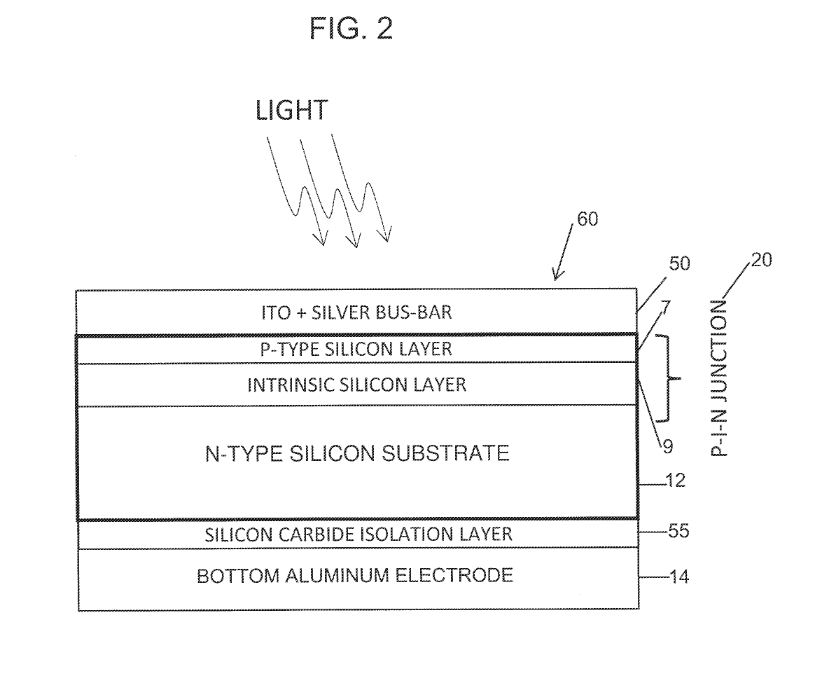

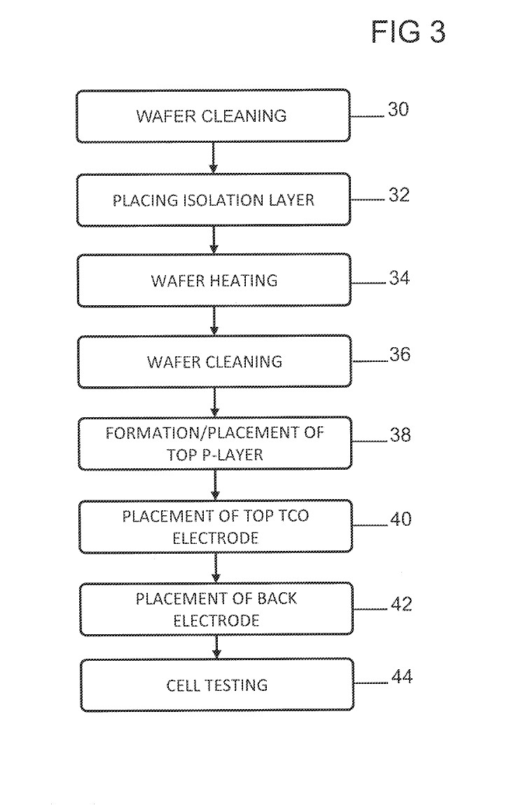

One embodiment of the present invention to fabricate a PV cell as shown at 60 in FIG. 2 uses a process as depicted in a block flow diagram of FIG. 3, which shows the following sequential steps:

Wafer cleaning step 30 in which a neutral detergent is used for the n-type silicon substrate (wafer) 12 and an organic neutral detergent is used for removal of the abrading agent.

Placing an isolation layer 55 preferably composed of SiC or SiO2 on the back or bottom surface of the silicon substrate 12 at step 32.

Wafer heating step 34 to form intrinsic silicon layer 9 on the top surface of substrate 12.

Wafer cleaning step 36, which is substantially the same as step 30.

Formation of a p-type silicon layer 7 on top of layer 9 by a boron (B) diffusion p layer or boron ion implantation at step 38.

Placement of a top TCO electrode in which ITO (indium tin oxide) as the TCO 5 is deposited on the resulting wafer by sputtering followed by an optional step of applying an anti-reflection coat of SiN, at step 40.

Placement of a bottom (back) electrode on the bottom surface of the resulting wafer below isolation layer 55, in which an aluminum paste 14 is screen-printed onto the wafer followed by firing.

Cell testing step 44 in which the resultant PV device 60 is run through a series of tests to determine its overall efficiency.

Now to describe the above steps carried out in Example 1 in further detail, a 6-inch N-type silicon single crystal wafer 12 having a resistivity of 1 to 5 (Ω cm), (100) crystal orientation is cleaned by a typical RCA cleaning method.

The substrate cleaning is performed in the following steps: (1) removing organic material using sulfuric acid-hydrogen peroxide water cleaning for ten minutes at 350° K; (2) using a pure water cleaning; (3) drying the resulting substrate with nitrogen, with an infrared treatment, and with ultraviolet light drying; and (4) cleaning the dried substrate with a 0.5% hydrofluoric acid solution. Subsequent cleaning by ammonium-hydrogen peroxide water at 350° K for 10 minutes, removing heavy metal contamination by 80° C. hydrochloric acid-hydrogen peroxide water cleaning solution for ten minutes after a pure water rinsing, and lastly pure water cleaning and nitrogen gas drying followed by paper IPA drying.

Next a SiC isolation layer 55 having a 200 nm thickness, is placed on the back surface of the resultant cleaned wafer 12 by means of a sputtering method. While the isolation layer in the present example is SiC, an SiO2 isolation layer may also be used. In addition, while the isolation layer thickness used in the present example is 200 nm, any other thickness above 100 nm may be used as well.

Following the previous step, a high resistivity layer 9 is formed on substrate 12 by the following method. Inert gas is introduced into a quartz boat containing the substrate 12 which had been previously vacuumed to approximately 1E-3 Pa. The quartz boat is heated and kept at pre-determined annealing temperature of 800° K or more for 30 minutes. While a vacuum of approximately 1E-3 Pa is used in the present example, the degree of the vacuum is not critical and any vacuum of approximately 20 Pa or lower can be used. Further, while argon gas was used as the inert gas in the present example, another inert gas such as helium gas and the like or a mixture of these inert gases may be used.

A variety of heating methods can be used to form intrinsic silicon layer 9, including but not limited to infrared heating, laser heating, and hot-wall furnace heating. In some embodiments, the particular heating methods used for treating the substrate layer have an effect on photovoltaic performance of the photovoltaic cell. In some embodiments, the cooling rate after the heating stage is a crucial factor to photovoltaic cell fabrication, whereas the heating rate is a less crucial factor to photovoltaic cell fabrication. Maximum photovoltaic cell performance can be obtained at heating temperatures above 1500° K, at heating times above 5 minutes, at approximately 1×10⁻³ Pa. The overall parameters used during heating step include temperatures ranging from 852 1700° Kelvin, heating times from one to 600 min., atmospheres from vacuum, argon, nitrogen or other inert gas at temperatures up to 1 atm. After the heating process is completed, the substrate is transformed into a photovoltaic semiconductor material having a high-resistivity layer therein.

After formation of the intrinsic silicon layer 9, the resulting substrate was cleaned by the use of a typical RCA cleaning method, similar to the one mentioned above.

After the cleaning step, a p-type silicon layer 7 is formed on top of layer 9 by means of boron (B) doping (diffusion) of the silicon wafer. In this example, boron nitride (BN) powder having a diameter between 2 and 20 microns was introduced in a heating chamber, then the quartz boat containing the silicon wafers is placed next to the BN powder and vacuumed to approximately 1 Pa. Next the heating chamber is heated and kept at a predetermined heating temperature of between 900 and 1200° K for 1 to 15 minutes. The amount of B diffusion into the intrinsic silicon layer varies according to heating temperature and time. In this example, the p-type silicon layer thickness was calculated to be 50 to 250 nm, for the temperature and time range mentioned above.

While B doping was used to create p-type silicon layer 7 in this example, p-type silicon layer 7, may be also formed by means of a B ion implantation method.

Next, a 150 nm thick ZnO transparent conductive film is formed over the p-type silicon layer 7 by a sputtering method to form top TCO electrode 50.

In this example, a silver paste bus-bar may be placed on top of the ZnO layer to improve overall electrical properties of top TCO electrode 50. Placement of the bus-bar is performed by a screen printing method.

While ZnO is used in the present example, other transparent conductive oxide films such as ITO, AZO, GZO, IZO, and NbO2, or a stacked structure thereof, may be used, and the transparent conductive oxide film may be formed by PLD, MOCVD, or a coating method, not limited to the sputtering method.

Next, a silicon nitride film may be formed consecutively as an anti-reflection film.

Lastly, Aluminum is coated by screen printing on the bottom (back) surface of the wafer 60 and heating is provided at 550° K for removing binder, and to complete the solar cell 60 construction.

While, a single crystal of 1 to 5 (Ω cm) and orientation (100) was used for the silicon substrate 12 in the present example, the face orientation may be (110) or (111), and solar grade silicon or poly- crystalline silicon may be used. When a silicon substrate having a different resistivity is used, it is necessary to change heating temperature and time.

### Example 2

### Top p-type Layer by Deposition: CVD, PVD, PLD

The following is another method for fabricating a PV cell 60 as shown in FIG. 2 of the present invention according to the process flowchart of FIG. 3.

In this example the steps for forming PV cell 60 are the same as in example 1, described above, except for process step 38, where the p-type silicon layer 7 is created. In this example 2, the p-type silicon layer 7 is deposited on top of the high resistivity layer by means of chemical vapor deposition (CVD). This p-type silicon layer may be an amorphous structure and of a thickness of approximately 5 to 100 nm.

While a CVD method is used to create a p-type silicon layer on top of the intrinsic silicon layer (or high resistivity layer) in this example, p-type silicon layer may be also formed by PVD, PLD, or some other coating method not limited to a sputtering method.

The foregoing description of preferred embodiments of the present invention has been provided for the purposes of illustration and description. It is not intended to be exhaustive or to limit the invention to the precise forms disclosed. Various additions, deletions and modifications are contemplated as being within its scope. The scope of the invention is, therefore, indicated by the appended claims rather than the foregoing description. Further, all changes which may fall within the meaning and range of equivalency of the claims and elements and features thereof are to be embraced within their scope.

We claim:

1. A PIN photovoltaic device comprising a first electrode layer, a p-type semiconductor layer, a high resistivity intrinsic semiconductor layer, an n-type semiconductor substrate; and a bottom electrode.

2. The device of claim 1 wherein said first electrode layer is a transparent conductive oxide (TCO).

3. The device of claim 1 wherein said first electrode layer is selected from the group consisting of ZnO ITO, ACO, GZO, IZO, and NbO2.

4. The device of claim 3 wherein said first electrode layer is ZnO.

5. The device of claim 4 further comprising placing a silver paste bus-bar on top of said first electrode layer.

6. The device of claim 1 further comprising an anti-reflecting coating on top of said first electrode layer.

7. The device of claim 1 wherein the resistivity of said intrinsic semiconductor layer is at least 10 times that of said n-type semiconductor substrate.

8. The device of claim 1 wherein said semiconductor substrate is an n-type single crystal silicon substrate having a resistivity in the range of about 1 to about five ohm·centimeter (Ω·cm).

9. The device of claim 1 further comprising a silicon carbide isolation layer between the semiconductor substrate and the bottom electrode.

10. The device of claim 1 wherein said p-type semiconductor layer is a p-type silicon layer.

11. The device of claim 1 wherein said bottom electrode is a metal layer having an ohmic contact with said n-type semiconductor substrate.

12. The device of claim 1 wherein said bottom electrode is aluminum.

13. A method of manufacturing a photovoltaic device having an n-type semiconductor substrate comprising performing the steps of: cleaning the n-type semiconductor substrate; introducing an inert gas under vacuum and a high temperature to form a high resistivity layer on the top surface of the substrate; forming a p-type semiconductor layer on the high resistivity layer; forming a transparent electrode layer on the p-type semiconductor layer; and forming a metal electrode on the bottom surface of the substrate.

14. The method of claim 13 wherein said n-type silicon substrate has a resistivity in the range of about 1 to about five ohm·centimeter (Ω·cm).

15. The method of claim 13 wherein said intrinsic semiconductor layer has a thickness of at least 100 nanometers (nm).

16. The method of claim 13 wherein said p-type semiconductor layer is a p-type silicon layer.

17. The method of claim 13 wherein said transparent electrode layer is a TCO layer selected from the group consisting of ZnO, ITO, ACO, GZO, IZO, and NbO2.

18. The method of claim 13 wherein said TCO layer is ZnO.

19. The method of claim 13 wherein said metal bottom electrode is aluminum.

20. A method of manufacturing a photovoltaic device having an n-type semiconductor substrate comprising performing the steps of: cleaning the n-type semiconductor substrate; forming an SiC or SiO2 isolation layer on the bottom surface of the substrate; introducing an inert gas under vacuum and a high temperature to form a high resistivity layer on the top surface of the substrate; depositing a p-type semiconductor layer on the high resistivity layer; forming a transparent electrode layer on the p-type semiconductor layer; and forming a metal electrode on the bottom surface of the substrate

21. The method of claim 20 wherein said transparent electrode layer is ZnO.

22. The method of claim 20 further comprising forming an anti-reflecting coating on the top of said transparent electrode layer, wherein said anti-reflective film is SiN.
